(19) United States
(12) Patent Application Publication
(10) Pub. No.: US 2024/0204049 A1
(43) Pub. Date: Jun. 20, 2024

(54) MEMORY DEVICE AND METHOD OF FABRICATING THE SAME

(71) Applicant: Winbond Electronics Corp., Taichung City (TW)

(72) Inventors: Ping-Lung Yu, Taichung City (TW); Po-Chun Shao, Taichung City (TW)

(73) Assignee: Winbond Electronics Corp., Taichung City (TW)

(21) Appl. No.: 18/083,556

(22) Filed: Dec. 18, 2022

(51) Int. Cl. H01L 29/08; H10B 41/27; H10B 43/27

(52) U.S. Cl. CPC H01L 29/0847; H10B 41/27; H10B 43/27

(57) ABSTRACT

A memory device includes a stack structure disposed above a substrate. The stack structure includes a plurality of stacks and a plurality of isolation layers alternating with each other. Each stack includes: a first source and drain layer; an insulating layer disposed on the first source and drain layer; a second source and drain layer disposed on the insulating layer; and a channel layer disposed on a sidewall of the insulating layer. A lower surface of the channel layer is connected to the first source and drain layer, and an upper surface of the channel layer is connected to the second source and drain layer. The memory device further includes a gate pillar extending through the stack structure; and a charge storage structure disposed between the channel layer and the gate pillar.

### BACKGROUND

### Technical Field

An embodiment of the disclosure relates to a semiconductor device and a method of fabricating the same, and more particularly, to a memory device and a method of fabricating the same.

### Description of Related Art

A non-volatile memory device (e.g. flash memory) is widely used as a memory device in personal computers and other electronic devices as a result of the advantage that the stored data does not disappear after a power outage. A NOR flash memory is a flash memory array commonly used in the industry at present. In order to further improve the aggregation degree of the memory device, a three-dimensional NOR flash memory has been developed. However, when stacked layers of the three-dimensional NOR flash memory are deposited, diffusion of dopant of a source and drain layer is likely to occur as a result of high temperature, so the dopant concentration and resistance of the source and drain layer are unable to be controlled.

### SUMMARY

An embodiment of the disclosure provides a memory device, which includes a stack structure, disposed above a substrate, in which the stack structure includes multiple stacks and multiple isolation layers alternating with each other, and each stack includes: a first source and drain layer; an insulating layer disposed on the first source and drain layer; a second source and drain layer, disposed on the insulating layer; and a channel layer, disposed on a sidewall of the insulating layer. A lower surface of the channel layer is connected to the first source and drain layer, and an upper surface of the channel layer is connected to the second source and drain layer. The memory device further includes a gate pillar extending through the stack structure, and a charge storage structure, disposed between the channel layer and the gate pillar.

An embodiment of the disclosure provides a method of fabricating a memory device which includes the following. A stack structure is formed above a substrate, in which the stack structure includes multiple stacks and multiple isolation layers alternating with each other, and each stack includes a first semiconductor layer, an insulating layer and a second semiconductor layer stacked in sequence. The stack structure is patterned to form a first opening. A portion of the first semiconductor layer and a portion of the second semiconductor layer exposed by a sidewall of the first opening is removed to form a first groove and a second groove, respectively. A third semiconductor layer and a fourth semiconductor layer are respectively formed in the first groove and the second groove, in which a doping concentration of the third semiconductor layer and the fourth semiconductor layer is greater than a doping concentration of the first semiconductor layer and the second semiconductor layer. A tempering process is performed for driving a dopant of the third semiconductor layer and the fourth semiconductor layer into the first semiconductor layer and the second semiconductor layer to form a first source and drain layer and a second source and drain layer. The insulating layer of the portion exposed by the sidewall of the first opening is removed to form a third groove. A channel layer is formed in the third groove. An insulating filling layer is formed in the first opening. A second opening is formed in the insulating filling layer. A charge storage structure and a gate pillar are formed in the second opening.

Based on the above, in the memory device and the method of fabricating the same of an embodiment of the disclosure, after the stacked layers are formed, the dopant of the source and drain layer is adjusted so that the source and drain layer has an appropriate concentration to reduce resistance.

### BRIEF DESCRIPTION OF THE DRAWING

FIG. 1A to FIG. 1G are perspective schematic diagrams of a method of fabricating a three-dimensional memory device according to an embodiment of the disclosure.

FIG. 2A to FIG. 2O are cross-sectional schematic diagrams of a fabricating process of a three-dimensional memory device according to an embodiment of the disclosure. FIG. 2A, FIG. 2B, FIG. 2C to FIG. 2K, FIG. 2L, FIG. 2M, FIG. 2N, and FIG. 2O are partial cross-sectional schematic diagrams of a tangent line I-I′ of FIG. 1A, FIG. 1B, FIG. 1C, FIG. 1D, FIG. 1E, FIG. 1F, and FIG. 1G, respectively.

FIG. 3A to FIG. 3C are cross-sectional schematic diagrams of a fabricating process of a three-dimensional memory device according to another embodiment of the disclosure.

### DESCRIPTION OF THE EMBODIMENTS

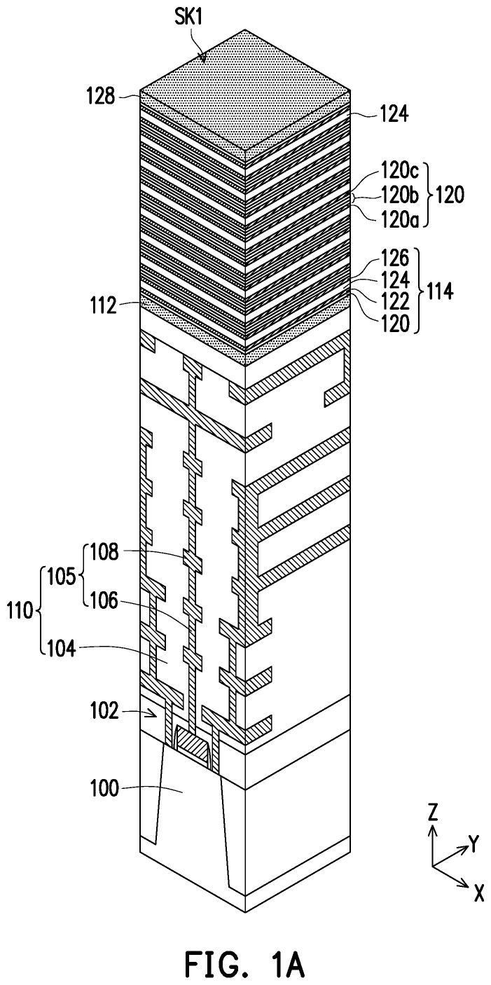

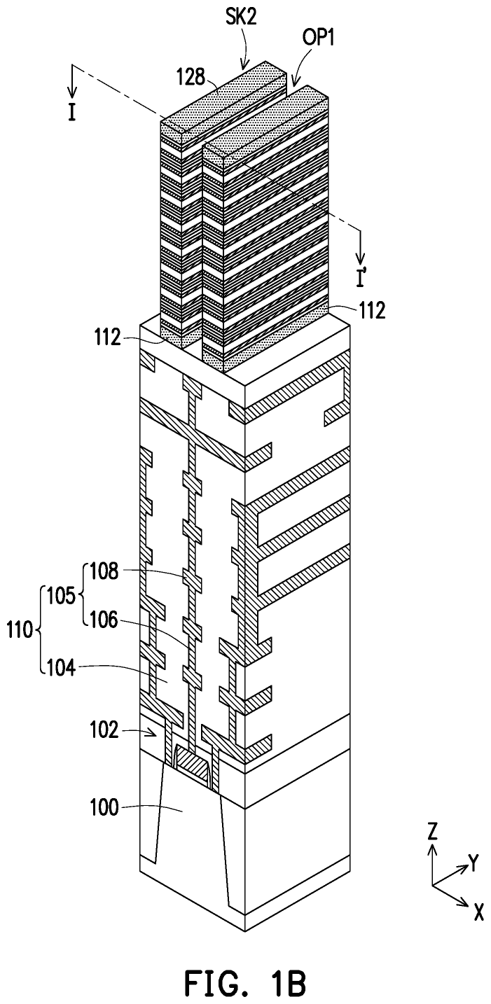

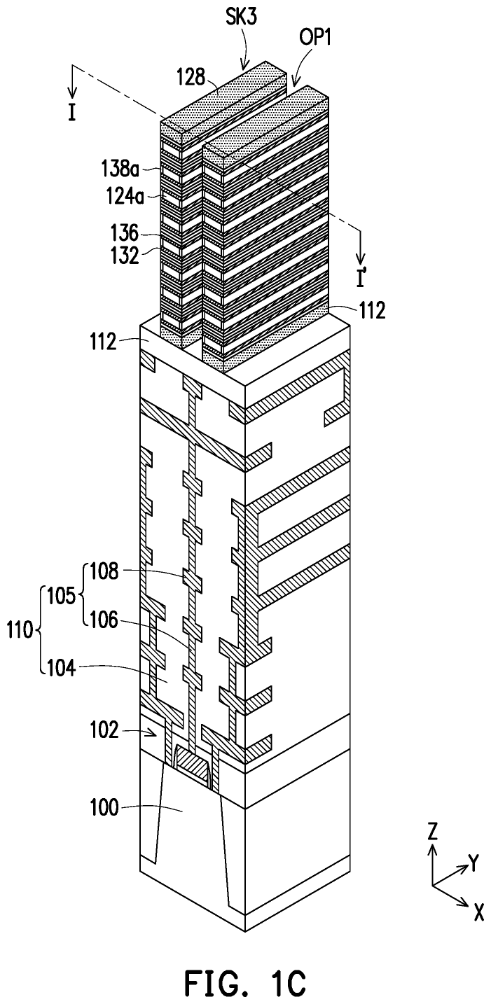

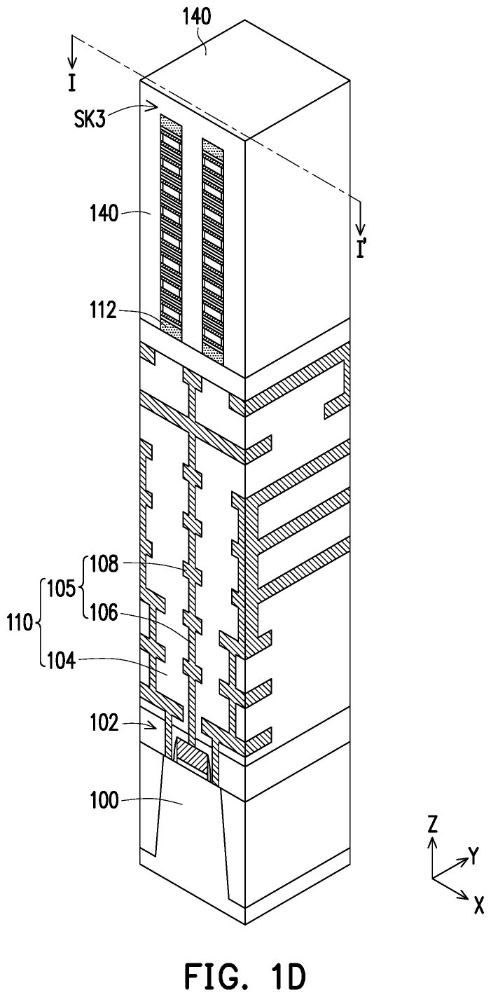

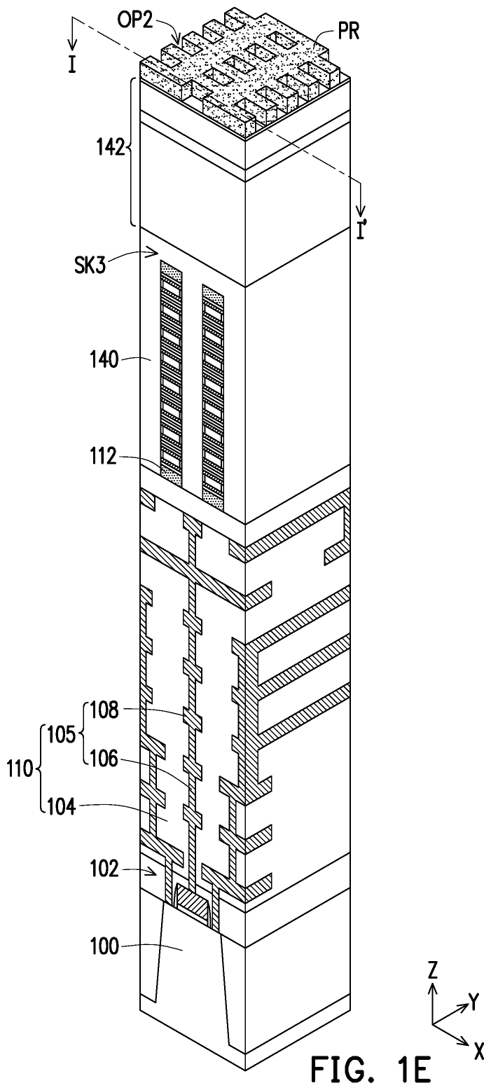

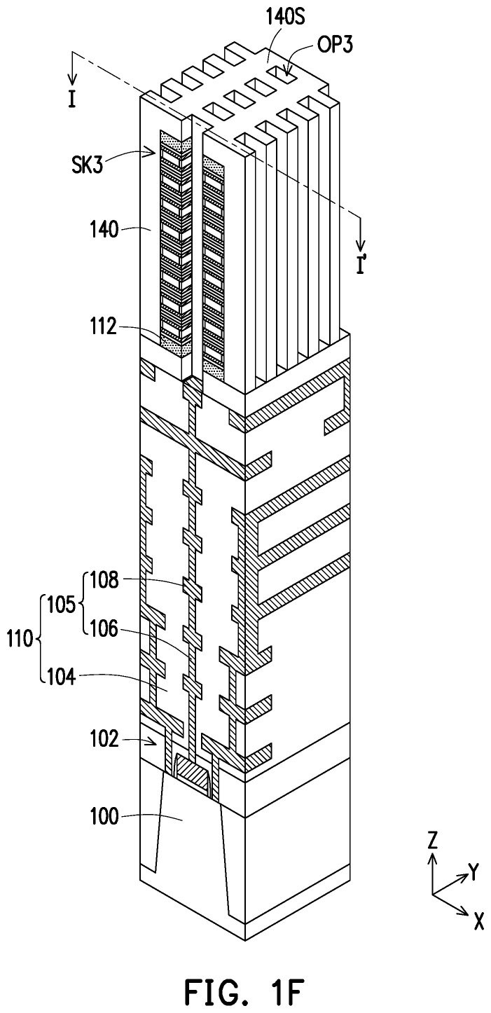

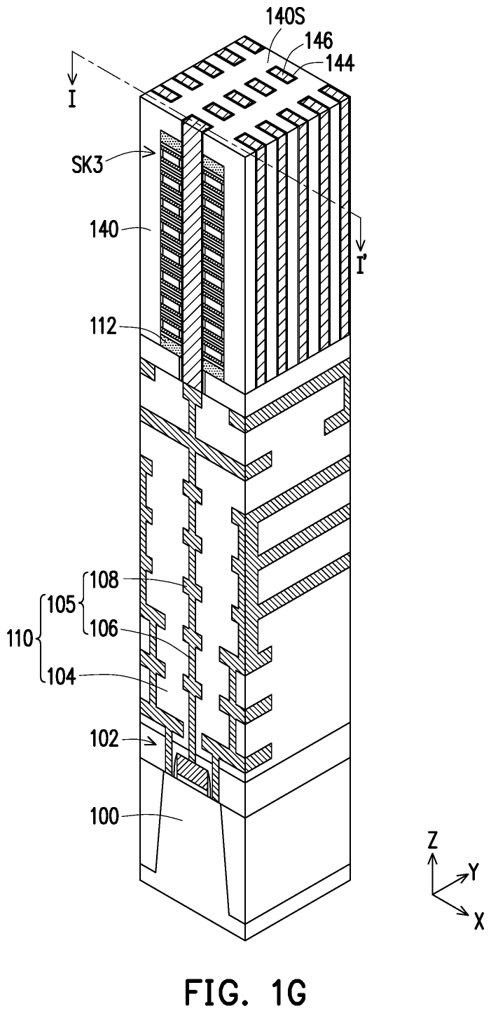

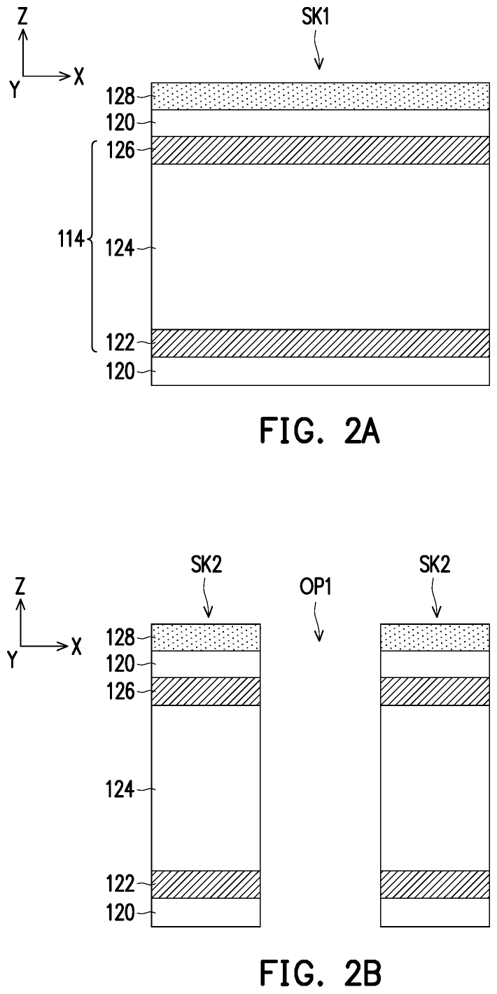

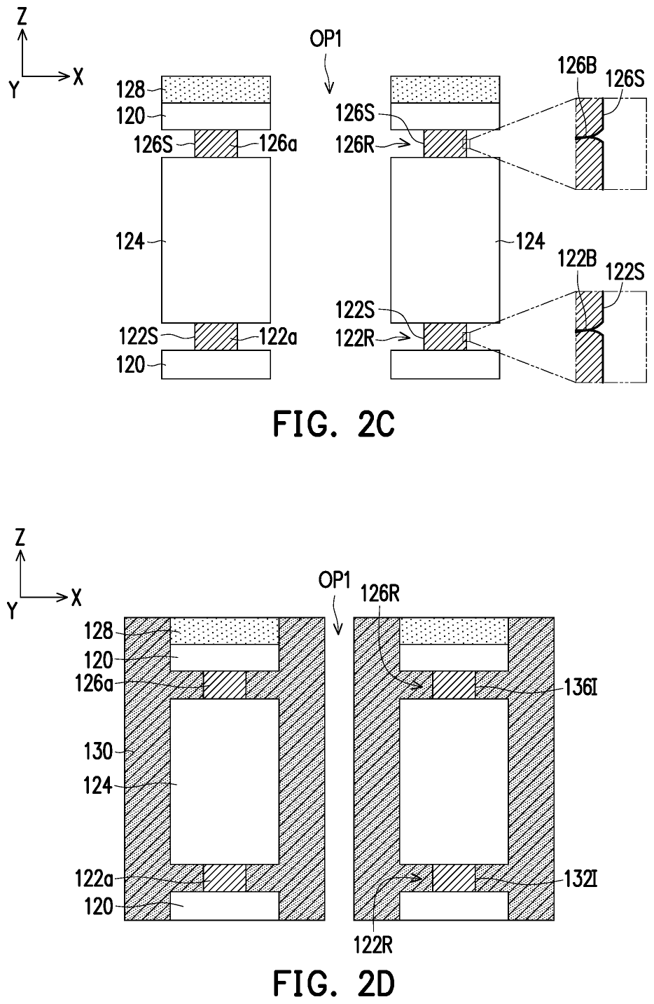

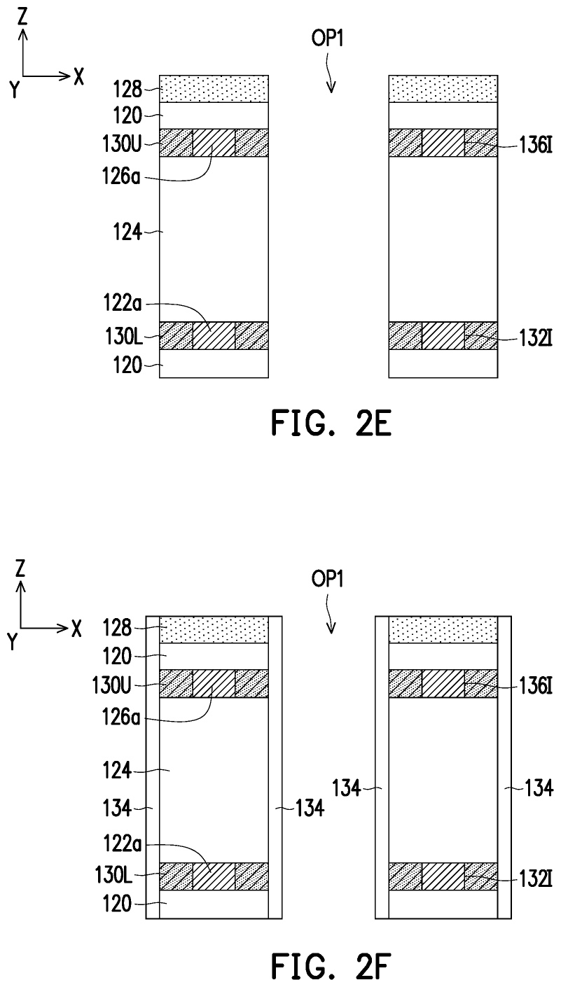

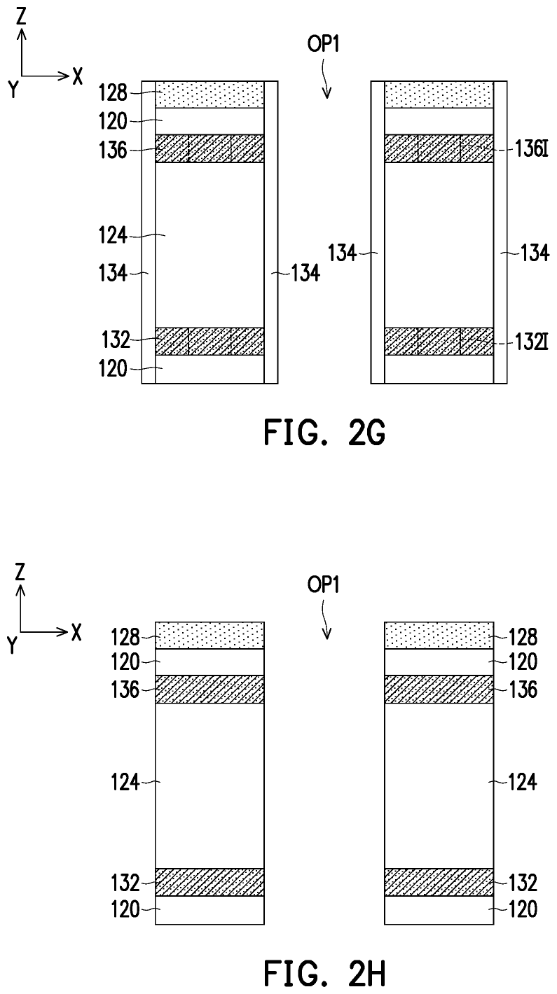

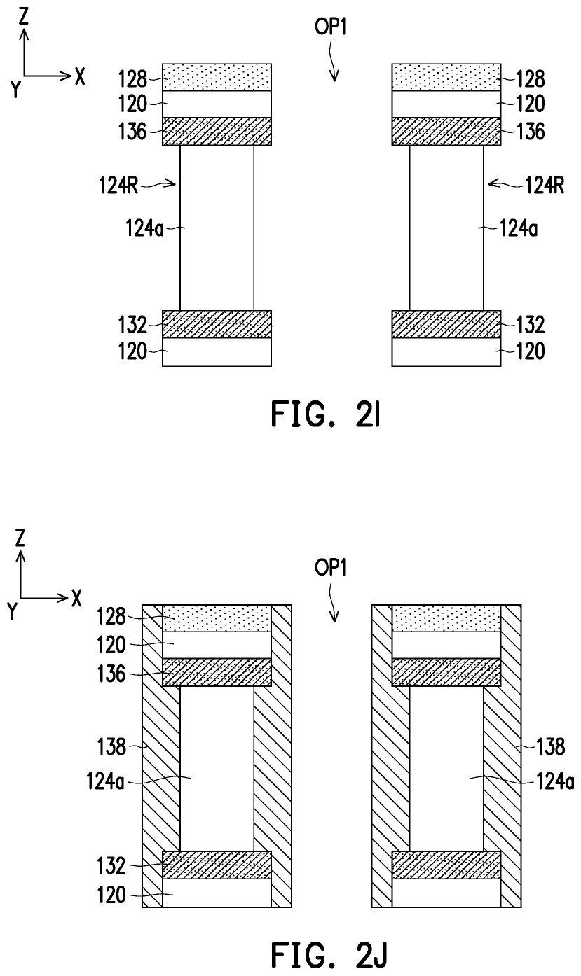

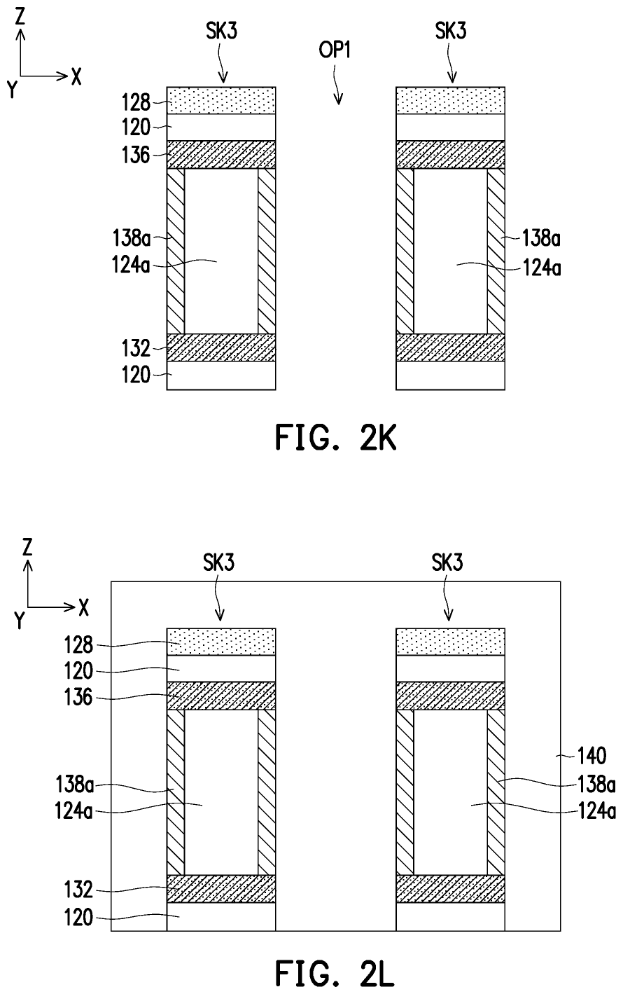

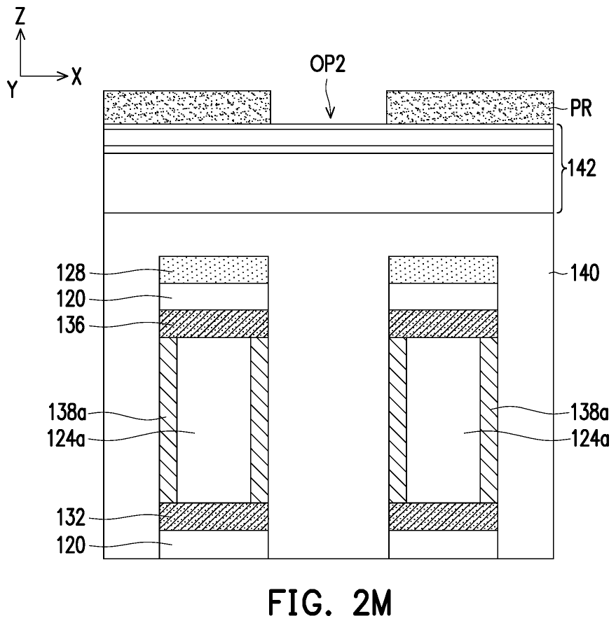

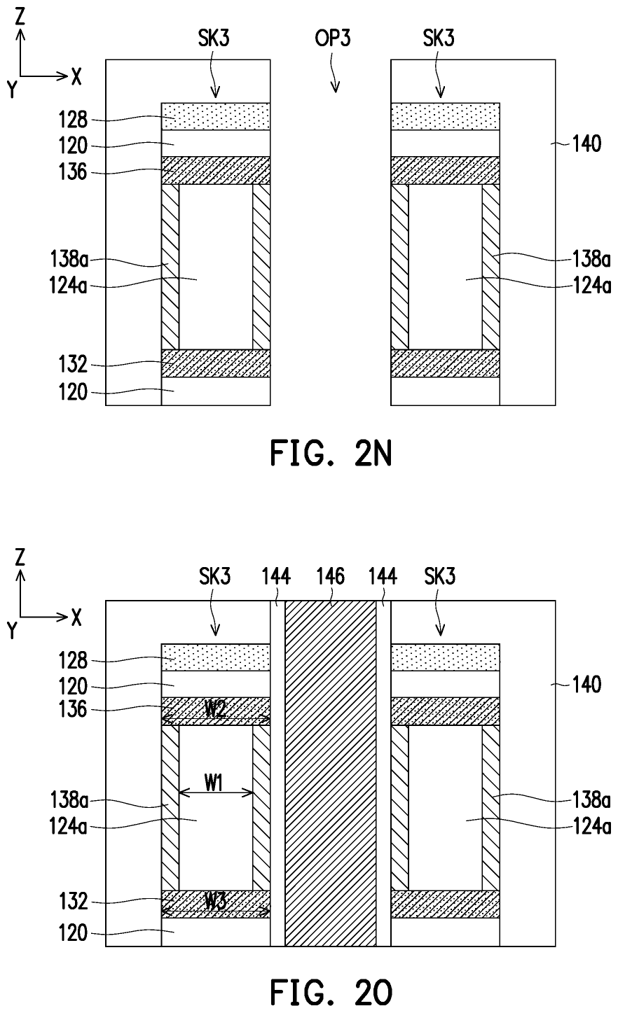

Referring to FIG. 1A and FIG. 2A, a substrate 100 is provided. The substrate 100 may be a semiconductor substrate, for example, a silicon-containing substrate. A device layer 102 is formed in sequence on the substrate 100. The device layer 102 may include an active device or a passive device. The active device is, for example, a transistor, a diode, etc. The passive device is, for example, a capacitor, an inductor, etc. The transistor may be an N-type metal-oxide-semiconductor (NMOS) transistor, a P-type metal-oxide-semiconductor (PMOS) transistor, or a complementary metal-oxide-semiconductor (CMOS) transistor, etc.

A metal interconnect structure 110 is formed on the device layer 102. The metal interconnect structure 110 may include multiple dielectric layers 104 and a metal interconnect 105 formed in the multiple dielectric layers 104. The metal interconnect 105 includes multiple plugs 106 and multiple wires 108. The dielectric layers 104 separate the adjacent wires 108. The wires 108 can be connected via the plugs 106, and the wires 108 can be connected to the device layer 102 via the plugs 106. In some embodiments, the metal interconnect structure 110 further includes a stop layer (not shown). The stop layer may be disposed between the dielectric layers 104 and/or on the topmost dielectric layers 104. The material of the stop layer is different from the material of the dielectric layers 104, for example, silicon nitride, silicon oxynitride, silicon carbide, aluminum oxide, or a combination thereof.

A stack structure SK1 is formed on the metal interconnect structure 110. The stack structure SK1 includes multiple stacks 114 and isolation layers 120 which are alternately stacked with each other. The number of the stacks 114 and the isolation layers 120 is not limited to what is shown in the figures.

Each of the stacks 114 includes a semiconductor layer 122, an insulating layer 124 and a semiconductor layer 126. The semiconductor layers 122 and 126 include polysilicon. The insulating layer 124 is silicon oxide, for example. The isolation layers 120 separate the stacks 114 from each other. The isolation layers 120 can be of a single layer or multiple layers, and the material thereof is, for example, silicon carbide or silicon nitride. In the example of FIG. 1A, the isolation layers 120 may include a layer 120a, a layer 120b, and a layer 120c, and material thereof are silicon carbide, silicon nitride, and silicon carbide, respectively.

The stack structure SK1 further includes stop layers 112 and 128 located under the bottommost of the stacks 114 and on the topmost of the stacks 114, respectively. The stop layers 112 and 128 include silicon nitride, silicon oxynitride or silicon carbide. The semiconductor layers 122 and 126, the insulating layer 124, the isolation layers 120, and the stop layers 112 and 128 of the stack structure SK1 can be formed in-situ in the same machine. Since the semiconductor layers 122 and 126 can be formed in-situ in the same machine as other layers of the stack structure SK1, in consideration of the overall deposition rate of the stack structure SK1, a doping concentration of the deposited semiconductor layers 122 and 126 cannot be too high. Therefore, the doping concentration of the semiconductor layers 122 and 126 is lower than the doping concentration of a semiconductor material layer 130 (shown in FIG. 2D) subsequently formed. The dopant of the semiconductor layers 122 and 126 are, for example, arsenic (As), boron (B), phosphorus (P), antimony (Sb), boron fluoride (BF₂) or indium (In), and the doping concentration may be lower than E17 atoms/cm³, for example, E12 atoms/cm³ to E17 atoms/cm³.

Referring to FIG. 1B and FIG. 2B, the stack structure SK1 is patterned to form a stack structure SK2 and multiple openings OP1. In some embodiments, the stack structure SK2 is multiple strips extending along the Y direction. The openings OP1 are, for example, a trench extending in the Y direction. In other embodiments, the stack structure SK2 is in the shape of a grid, and the periphery of the openings OP1 is surrounded by the stack structure SK2 (not shown).

FIG. 2C to FIG. 2K are partial cross-sectional schematic diagrams of a tangent line I-I′ of FIG. 1C.

Referring to FIG. 2C, a pullback process is performed on the semiconductor layers 122 and 126 to form semiconductor layers 122a and 126a and multiple grooves 122R and 126R. The pullback process is, for example, an etching process. The semiconductor layer 122a and the semiconductor layer 126a expose crystal grains that are incomplete, and sidewalls 122S and 126S formed by the semiconductor layer 122a and the semiconductor layer 126a have a greater degree of undulation (roughness) than a degree of undulation of grain boundaries 122B and 126B of the crystal grains in the semiconductor layers 122a or 126a.

Referring to FIG. 2D and FIG. 2E, a semiconductor material layer 130 is deposited in the openings OP1, and the semiconductor material layer 130 is filled into the grooves 122R and 126R and in contact with the semiconductor layers 122a and 126a, and between the semiconductor material layer 130 and the semiconductor layer 122a, there is an interface 1321, and between the semiconductor material layer 130 and the semiconductor layer 126a, there is an interface 1361. The semiconductor material layer 130 is, for example, a doped polysilicon layer formed by chemical vapor deposition. In some embodiments, the semiconductor material layer 130, the semiconductor layers 122a and 126a are all doped semiconductor layers, and the doping concentration of the semiconductor layer 130 is greater than the doping concentration of the semiconductor layers 122a and 126a. The dopant of the semiconductor layer 130 is, for example, As, B, P, Sb, BF₂ or In, and the doping concentration may be greater than E12 atoms/cm³, for example, E12 atoms/cm³ to E21 atoms/cm³.

Afterwards, a partial removal process is performed to remove the semiconductor material layer 130 outside the grooves 122R and 126R, so as to form semiconductor layers 130L and 130U in the grooves 122R and 126R, respectively. Between the semiconductor layer 130L and the semiconductor layer 122a, there is the interface 1321, and between the semiconductor layer 130U and the semiconductor layer 126a, there is the interface 1361.

Referring to FIG. 2F, a blocking spacer 134 is formed on a sidewall of the openings OP1. The material of the blocking spacer 134 is, for example, silicon nitride, silicon oxynitride or a combination thereof. The blocking spacer 134 is formed by, for example, firstly forming a blocking layer to cover the sidewall and a bottom surface of the openings OP1, and afterwards performing an anisotropic etching process to remove the blocking layer covering the top surface of a stop layer 128 and the bottom surface of the openings OP1.

Referring to FIG. 2G, a tempering process is performed for driving the dopant of the semiconductor layers 130L and 130U into the semiconductor layers 122a and 126a. During the tempering process, the blocking spacer 134 can prevent the dopant of the semiconductor layers 130L and 130U from diffusing to other regions, so that the dopant of the semiconductor layers 130L and 130U diffuse toward the semiconductor layers 122a and 126a to form source and drain layers 132 and 136. The temperature of the tempering process is, for example, 400 degrees Celsius to 1200 degrees Celsius. The doping concentration of the source and drain layers 132 and 136 are, for example, E12 atoms/cm³ to E21 atoms/cm³. In some embodiments, interfaces 1321 and 1361 also exist in the source and drain layers 132 and 136.

Referring to FIG. 2H and FIG. 2I, the blocking spacer 134 is removed. Afterwards, a pullback process, such as the anisotropic etching process, is performed on the insulating layer 124 of the stacks 114 to form an insulating layer 124a and a groove 124R.

Referring to FIG. 2J and FIG. 2K, a semiconductor layer 138 is formed in the openings OP1, and the semiconductor layer 138 is filled into the groove 124R. The semiconductor layer 138 is, for example, a polysilicon layer. Afterwards, a partial removal process is performed on the semiconductor layer 138 to form a channel layer 138a in the groove 124R. The channel layer 138a is located on a sidewall of the insulating layer 124a. Upper and lower surfaces of the channel layer 138a are connected and contact the source and drain layers 132 and 136, respectively. In some embodiments, a sidewall of the channel layer 138a is aligned with the contacted source and drain layers 132 and 136. So far, a stack structure SK3 is formed, as shown in FIG. 1C and FIG. 2K.

Referring to FIG. 1D and FIG. 2L, an insulating filling layer 140 is formed on the substrate 100, and the insulating filling layer 140 is filled into the openings OP1. The material of the insulating filling layer 140 is, for example, silicon oxide.

Referring to FIG. 1E and FIG. 2M, a multilayer 142 and a mask layer PR are formed on the insulating filling layer 140. The multilayer 142 may include an anti-reflective layer, a hard mask layer, and the like. The mask layer PR is, for example, a patterned photoresist layer, and has multiple openings OP2.

Referring to FIG. 1F and FIG. 2N, a patterning process is performed to transfer the mask layer PR to the insulating filling layer 140 and the stack structure SK3 to form a hole OP3. In some embodiments, the hole OP3 is arranged in an array. Afterwards, the mask layer PR and a hard mask layer 142 are removed.

Referring to FIG. 1G and FIG. 2O, a charge storage structure 144 and a gate pillar 146 are formed in the hole OP3. The charge storage structure 144 and the gate pillar 146 are formed by, for example, forming a charge storage material layer on an upper surface of the insulating filling layer 140 and in the hole OP3, and then removing the charge storage material layer on a bottom surface of the hole OP3 through an etch back process. Afterwards, a gate material layer is formed on the upper surface of the insulating filling layer 140 and in the hole OP3, and then a planarization process is performed by a chemical mechanical polishing method to remove the excess gate material layer on the upper surface of the insulating filling layer 140. The charge storage material layer is, for example, an oxide/nitride/oxide (ONO) composite layer. The gate material layer is, for example, a conductor layer. The conductor layer includes a barrier layer and a metal layer. The material of the barrier layer includes titanium (Ti), titanium nitride (TiN), tantalum (Ta), tantalum nitride (TaN) or a combination thereof, and the material of the metal layer includes tungsten (W). In some embodiments, the gate pillar 146 is arranged in an array. The gate pillar 146 of two adjacent columns may be staggered or aligned. An insulating filling layer 140S between the gate pillar 146 of the two adjacent columns can be used as a slit.

The gate pillar 146 extends continuously in the Z direction and is electrically connected to the metal interconnect 105 below. The charge storage structure 144 extends continuously in the Z direction and surrounds a sidewall of the gate pillar 146. The charge storage structure 144 is sandwiched between the sidewall of each channel layer 138a and the sidewall of the gate pillar 146. The source and drain layer 132, the insulating layer 124a, and the source and drain layer 136 are stacked in the Z direction. A width W1 of the insulating layer 124a in the X direction is smaller than widths W2 and W3 of the source and drain layers 132 and 136. The channel layer 138a is disposed on the sidewall of the insulating layer 124a. The lower surface of each channel layer 138a is connected to the source and drain layer 132, and the upper surface of each channel layer 138a is connected to the source and drain layer 136. In addition, multiple channel layers 138a in the Z direction are separated from each other.

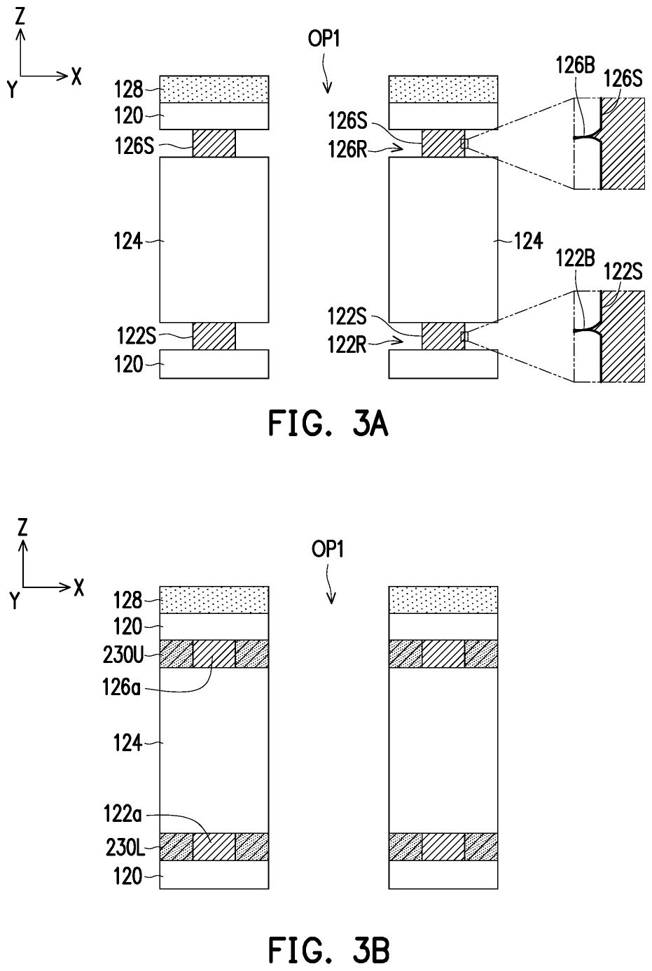

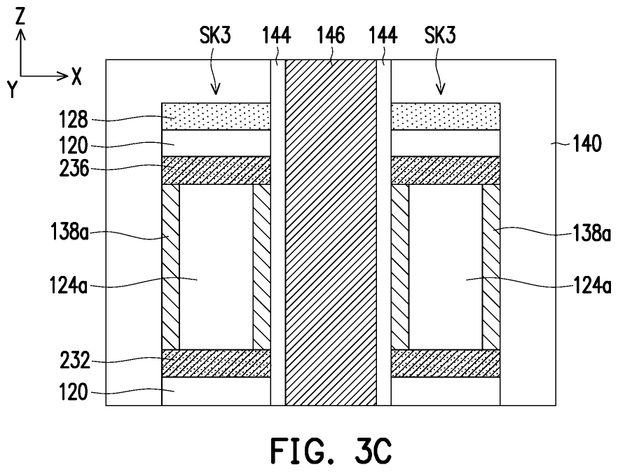

The method of forming the source and drain layers 132 and 136 of the disclosure is not limited to the above embodiments. In other embodiments, the method of forming the source and drain layers 132 and 136 is as follows. Referring to FIG. 3A, the semiconductor layers 122a and 126a and the multiple grooves 122R and 126R are formed according to the above-mentioned method. Afterwards, an epitaxial growth process is performed to form epitaxial layers 230L and 230U in the grooves 122R and 126R, as shown in FIG. 3B. The epitaxial layers 230L and 230U are also called semiconductor layers. Afterwards, according to the process of FIG. 2F to FIG. 2H, the source and drain layers 132 and 136, the charge storage structure 144 and the gate pillar 146 are formed, as shown in FIG. 3C.

The source and drain layer is formed in multiple stages in the embodiment of the disclosure. First, the semiconductor layer with a lower concentration is formed in accordance with the process, and then the sidewall of the semiconductor layer is partially removed, and the semiconductor layer (epitaxy layer) with a high concentration is formed in the formed groove. Thereafter, through the tempering process, the dopant with a high concentration is diffused and driven into the semiconductor layer with the lower concentration to form the source and drain layer with the appropriate doping concentration. In this way, the stack structure with the stack and the insulating layer can be formed in-situ in the same machine, and after the stack structure is formed, the concentration of the source and drain layer can be adjusted so that the source and drain layer has the appropriate concentration to reduce resistance.

What is claimed is:

1. A memory device, comprising:
a stack structure disposed above a substrate, wherein the stack structure comprises a plurality of stacks and a plurality of isolation layers alternating with each other, and each stack comprises:
a first source and drain layer;
an insulating layer, disposed on the first source and drain layer;
a second source and drain layer, disposed on the insulating layer; and
a channel layer, disposed on a sidewall of the insulating layer, wherein a lower surface of the channel layer is connected to the first source and drain layer, and an upper surface of the channel layer is connected to the second source and drain layer;
a gate pillar, extending through the stack structure; and
a charge storage structure, disposed between the channel layer and the gate pillar.

2. The memory device according to claim 1, wherein the first source and drain layer and the second source and drain layer have an interface.

3. The memory device according to claim 1, wherein a sidewall of the first source and drain layer and the second source and drain layer is aligned with a sidewall of the channel layer.

4. The memory device according to claim 1, further comprising:
a metal interconnect structure, disposed between the stack structure and the substrate,
wherein the gate pillar is electrically connected to a metal interconnect of the metal interconnect structure.

5. A method of fabricating a memory device, comprising:
forming a stack structure above a substrate, wherein the stack structure comprises a plurality of stacks and a plurality of isolation layers alternating with each other, and each stack comprises a first semiconductor layer, an insulating layer and a second semiconductor layer stacked in sequence;
patterning the stack structure to form a first opening;
removing a portion of the first semiconductor layer and a portion of the second semiconductor layer exposed by a sidewall of the first opening to form a first groove and a second groove, respectively;
forming a third semiconductor layer and a fourth semiconductor layer respectively in the first groove and the second groove, wherein a doping concentration of the third semiconductor layer and the fourth semiconductor layer is greater than a doping concentration of the first semiconductor layer and the second semiconductor layer;
performing a tempering process for driving a dopant of the third semiconductor layer and the fourth semiconductor layer into the first semiconductor layer and the second semiconductor layer to form a first source and drain layer and a second source and drain layer;
removing the insulating layer of the portion exposed by the sidewall of the first opening to form a third groove;
forming a channel layer in the third groove;
forming an insulating filling layer in the first opening;
forming a second opening in the insulating filling layer; and
forming a charge storage structure and a gate pillar in the second opening.

6. The method of fabricating the memory device according to claim 5, wherein a method of forming the third semiconductor layer and the fourth semiconductor layer comprises:
depositing a semiconductor material layer on the substrate and filling the first opening and the first groove and the second groove; and
performing a partial removal process to remove the semiconductor material layer outside the first groove and the second groove.

7. The method of fabricating the memory device according to claim 5, wherein a method of forming the third semiconductor layer and the fourth semiconductor layer comprises performing an epitaxial growth process to form a first epitaxial layer and a second epitaxial layer in the first groove and the second groove, respectively.

8. The method of fabricating the memory device according to claim 5, wherein the first semiconductor layer, the insulating layer, the second semiconductor layer, and the isolation layers are formed in-situ in a same machine.

9. The method of fabricating the memory device according to claim 5, further comprising:
forming a metal interconnect structure on the substrate before forming the stack structure above the substrate,
wherein the gate pillar is electrically connected to a metal interconnect of the metal interconnect structure.

10. The method of fabricating the memory device according to claim 5, further comprising:
forming a blocking spacer on the sidewall of the first opening before performing the tempering process; and
removing the blocking spacer after performing the tempering process.

11. The method of fabricating the memory device according to claim 10, wherein a material of the blocking spacer comprises silicon nitride, silicon oxynitride or a combination thereof.
